(19) United States
(12) Patent Application Publication
(10) Pub. No.: US 2007/0062647 A1
(43) Pub. Date: Mar. 22, 2007

(54) Method and apparatus for isolative substrate edge area processing

(76) Inventors: Joel B. Bailey, Austin, TX (US); Jonathan Doan, Austin, TX (US); Paul F. Forderhase, Austin, TX (US); Johnny D. Ortiz, Round Rock, TX (US); Michael D. Robbins, Round Rock, TX (US)

Correspondence Address: HARNESS, DICKEY & PIERCE, P.L.C., P.O. BOX 828, BLOOMFIELD HILLS, MI, 48303, US

(21) Appl. No.: 11/230,263

(22) Filed: Sep. 19, 2005

(51) Int. Cl. H01L 21/306; C23F 1/00

(52) U.S. Cl. 156/345.33; 156/345.51; 438/691

(57) ABSTRACT

An isolative substrate edge area processing method and apparatus is described. The apparatus has an isolator for isolating and processing by dry chemical technique a portion of a substrate including a substrate edge region. The isolator has nozzles for directing a flow of reactive species towards the edge area of the substrate and a purge plenum for biasing flow of reactive species towards an exhaust plenum while the substrate rotates on a chuck. Tuned flow control prevents migration of reactive species and reaction byproducts out of the processing area. A method for processing a substrate with the isolator involves directing a flow of reactive species at an angle towards an edge area of the substrate while forming a boundary around the processing area with flow control provided by the purge plenum, and exhaust plenum.

### FIELD OF THE INVENTION

The present invention relates to a method and apparatus for processing edge regions of a substrate and more particularly, a method and apparatus for dry chemical processing the edge area of the substrate in isolation from the remainder of the substrate.

### BACKGROUND

During the manufacture of integrated circuits, silicon substrate wafers receive extensive processing including deposition and etching of dielectrics, metals, and other materials. At varying stages in the manufacturing process it is necessary to “clean” the edge area of the wafer to remove unwanted films and contaminants including particles that develop as a result of the wafer processing. This includes films and contaminants that develop on a near edge top surface (primary processed side), near edge back surface, and edge (including, top bevel, crown and bottom bevel) of the wafer (hereinafter “edge area” refers generally to the near edge top surface, near edge bottom surface, and edge in combination or individually). Removal of films and contaminants is desirable to prevent the potential of particulate migration into the device portion of the wafer. Potential contaminant particles are generated during wafer handling, processing, and as a result of “pop-off” effect due to film stress.

It is a challenge to process and thus remove edge area thin films and contaminants in an efficient and cost effective manner without effecting the remainder of the wafer that contains in-process devices. This challenge is exacerbated by use of chemistries and processes that may adversely impact the in-process device portion of the wafer.

Generally, various known options exist for effecting removal of films and contaminants. Etching can occur in a wet or dry processing environment. Wet chemical etching refers to the contact of the wafer surface with a liquid chemical etchant. Material is removed as an agitated liquid or spray, for example, passes over the substrate surface. Dry etching generally refers to the contact of the substrate surface with a gaseous plasma etchant.

Wet chemical etching is used extensively in wafer processing. In wet chemical etching the chemical reactants in a liquid or vapor state are transported by diffusion to the reacting surface, chemical reactions occur at the surface, and the products from the surface are removed. However, chemical etching has its limitations and is not desirable in all applications. It is difficult to isolate wet chemical etching to the near edge of the wafer. Further, etched material constituents may move within etched or partially etched openings on the wafer surface. Also, wet etching may result in incomplete or non-uniform etching and is isotropic resulting in an imprecise etch. In addition, wet etching requires repeated drying of the wafer between processing steps thus adding time and cost to the process. Cost of consumables and undesirable water consumption volume is a problem with wet process.

Dry etching usually meaning plasma assisted etching denotes several techniques that use plasma in the form of low pressure discharges. Dry etch plasma methods include plasma etching, reactive ion etching (RIE), sputter etching, reactive ion beam etching and other plasma based etching methods. A plasma is produced when an electric field (or electromagnetic field) of sufficient magnitude is applied to the gas, causing the gas to break down and become ionized. For this reason, a plasma is a fully or partially ionized gas.

However, dry, plasma based etching has its own limitations and problems. This includes difficulty in processing only a part of the wafer, for example, the wafer edge area. Diffusion effects dominate at low operating pressures making it difficult to control exposure location on the wafer. Further, equipment overhead for these processes is cumbersome, requiring vacuum chambers and pumping equipment. Vacuum requirements can also reduce throughput and increase equipment and operating costs. Ion induced damage to the wafer is also a concern. Charge differential in the plasma can also cause electrostatic damage to devices on the wafer.

A difficult aspect of processing the edge of the substrate is the ability to limit migration of reactive chemistries, byproducts, and contaminants from the edge area being processed to the non-processed area away from the edge. Even small (measured on a parts per billion basis) amounts of contaminants can have a significant impact on final product yield.

Apart from wet chemical and dry plasma-based processing, abrasive polishing methods have been used to treat bevel and crown areas of the wafer edge. These methods, however, are inherently dirty and tend to cause particulate contamination and subsequent defects in the substrate. This necessitates a post-treatment step of additional cleaning. Another issue with abrasive methods is sub-surface damage left after the process. This damage is induced in the substrate Si crystalline structure as a result of the process and can have negative effects during subsequent processing.

Other edge area processing systems are limited in the control of the area processed and can result in edge area topographies that can trap particles and induce defects. In addition some of these systems require expensive consumable chemicals and generate large volumes of hazardous waste.

Therefore, each of the above described processes and systems has inherent limitations and problems that restrict its suitability for certain applications particularly where the requirement is for cleaning a film or contaminant from the wafer edge area and isolating the remainder of the wafer from the process. There is a need for an apparatus and method for processing the edge area of substrates that avoids the inherent problems with wet chemical, dry ionic plasma, and abrasive methods of processing a wafer edge area. It is important that the method and apparatus be efficient, cost effective and not result in damage or the necessity of performing further process steps on the wafer. It is important that the method and apparatus work in a non-vacuum (substantially atmospheric pressure) to reduce costs associated with vacuum based systems.

### SUMMARY OF THE INVENTION

In accordance with the present invention an edge area substrate processing method and apparatus provides advantages over the aforementioned processing methods and systems. An aspect of the present invention is directed to a method and apparatus for dry chemical processing at atmospheric pressure the edge area of a substrate in isolation from the remainder of the substrate. In another aspect of the invention a substrate edge area processing apparatus comprises an isolator for isolating a portion of the substrate edge area to be processed. In a further aspect of the invention one or more grooves in the isolator form a plenum for confining flow of a reactive species to the edge area of the substrate. In an additional aspect of the invention one or more nozzles are disposed in the isolator with at least one of the one or more nozzles at an angle between perpendicular and horizontal to the top surface of the substrate. The one or more nozzles are for emitting a reactive species for reacting with a material on the substrate edge area. In a further aspect of the invention pressure differentials bias the reactive species away from the area of the substrate outside of the isolator.

An additional aspect of the invention also provides a substrate edge processing method for isolating and processing a portion of a substrate wherein the portion to be processed extends from an edge of the substrate radially across the top surface of the substrate to another part of the edge of the substrate thus isolating an edge area to be processed, the method comprising forming a pressure differential barrier between the portion of the substrate being processed and the remainder of the substrate and directing a reactive species towards the processed portion of the substrate at an angle greater than parallel to the top surface of the substrate and less than vertical to the top surface of the substrate.

A further aspect of the invention also includes substrates, particularly wafers, manufactured or processed by the method or apparatus of the invention.

Thus, the invention advantageously provides for a cost effective, efficient method and apparatus for processing the edge area of a substrate. An edge area of the substrate to be processed is isolated from the remainder of the substrate by directing a flow of an inert gas through a plenum near the area to be processed thus forming a barrier while directing a flow of reactive species at an angle relative to the top surface of the substrate towards the substrate edge area thus processing the substrate edge area. A flow of inert gas into the processing chamber together with a negative exhaust pressure may contribute to the biasing of reactive species and other gases away from the non-processing areas of the substrate.

The described method and apparatus allows for precise processing of portions of the substrate particularly the substrate edge area without allowing for encroachment in the excluded area. Flow control as a part of the apparatus isolator structure in combination with pressure differentials effectively limits movement of reactive species into the area excluded. Using directed flow of the reactive species to the edge area of the substrate allows for a high etch rate and resulting overall significant improvement of throughput of processed substrates. In sum, the invention provides for a clean, effective, and efficient method and apparatus for processing the edge area of substrates in a manner that is highly desired for achieving low contamination of the device portion of the substrate.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 shows a schematic side view of a substrate edge area processing system as a preferred embodiment of the present invention;

FIG. 2 shows a schematic top view of the preferred embodiment as shown in FIG. 1;

FIG. 3 shows a schematic cross-sectional side view of the preferred embodiment as shown in FIG. 1;

FIG. 4 shows a schematic cross-sectional view of the bottom half of the preferred embodiment as shown in FIG. 1 with a cut-away of a substrate;

FIG. 5 shows a detailed view of a portion of the isolator of the preferred embodiment as shown in FIG. 1;

FIG. 6 shows a cross-sectional view of a substrate wafer of the type to be processed with the preferred embodiment as shown in FIG. 1;

FIGS. 7A-7F show cross-sections of substrate wafers with thin films in pre-processed and post-processed condition;

FIG. 8 shows a schematic cross-sectional view of an alternative embodiment of the invention;

FIG. 9 shows a schematic top view of the alternative embodiment as shown in FIG. 8;

FIG. 10 shows a schematic cross-sectional side view of a second alternative embodiment of the invention;

FIG. 11 shows a schematic cross-sectional side view of third alternative embodiment of the invention;

FIG. 12 shows a schematic cross-sectional view of a fourth alternative embodiment of the invention as shown in FIG. 1 with additional components; and

FIG. 13 shows a schematic top view of a fifth alternative embodiment of the invention.

### DETAILED DESCRIPTION OF THE PREFERRED EMBODIMENTS

The following description of the preferred embodiments is merely exemplary in nature and is in no way intended to limit the invention, its application, or uses.

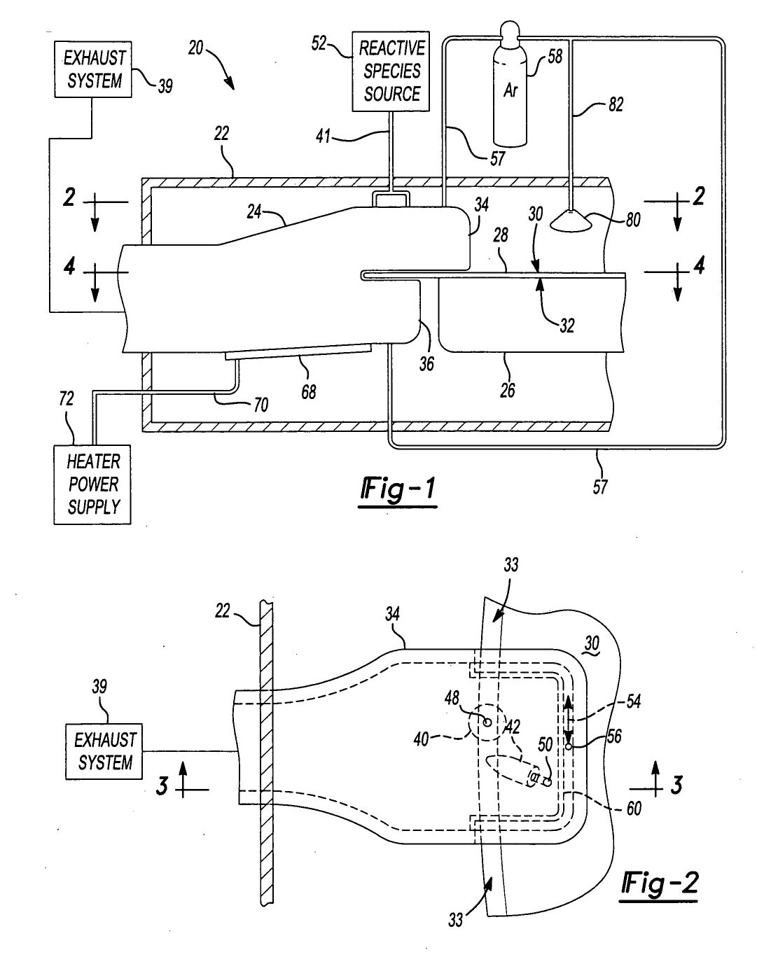

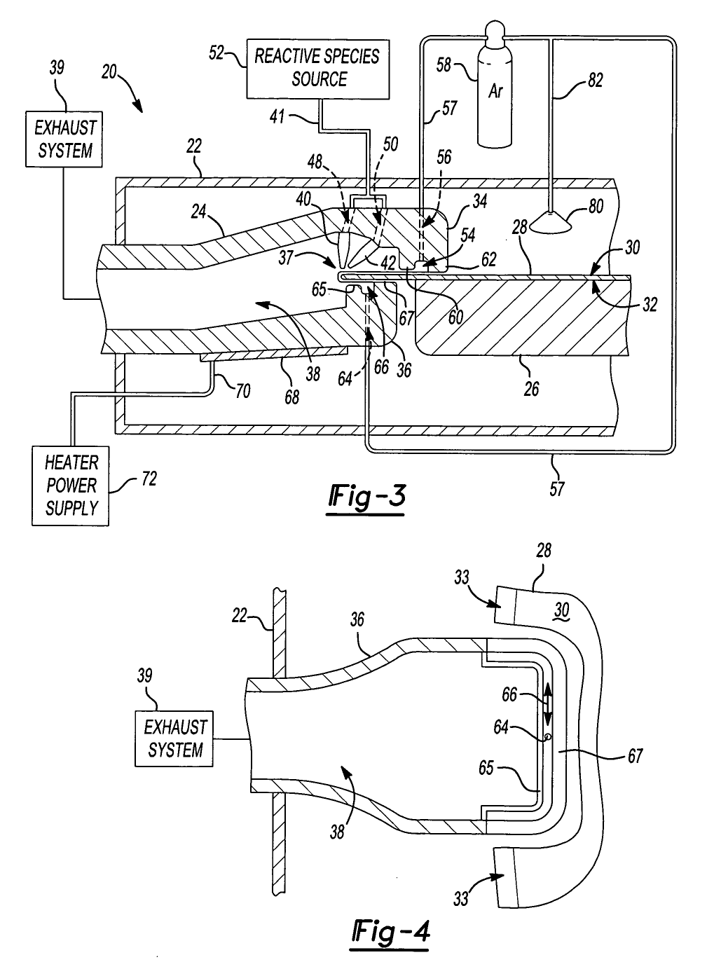

Referring to FIGS. 1-5 a preferred embodiment of the wafer edge area processing system 20 (the “System”) of the invention has a processing chamber 22 with an isolator 24 and wafer chuck 26 disposed therein. A wafer 28 is retained on top of the wafer chuck 26, the wafer 28 having a top surface 30, bottom surface 32, and edge area 33 (including edge and near edge as shown by lighter line proximal to edge) that surrounds the radial perimeter of the wafer 28. The isolator 24 has an upper section 34 extending over a portion of the top surface 30 of the wafer 28 and a lower section 36 extending over a portion of the bottom surface 32 of the wafer 28. The inside of the isolator 24 has a processing area 37 for processing the edge area 33 of the wafer 28. The processing area 37 leads into an exhaust plenum 38 connected to an exhaust system 39 for exhausting gases, process byproducts, and condensation.

Disposed within the upper section 34 of the isolator 24 are a first nozzle 40 and a second nozzle 42. Both nozzles are for emitting a directed flow of reactive species towards the edge area 33 of the wafer 28. First nozzle 40 is offset from an axis perpendicular to a plane that is common with the top surface 30 of the wafer 28 (the “wafer plane”). First nozzle 40 is pointed towards the top surface 30 at an angle of 80° +/−5° relative to the wafer plane. Second nozzle 42 is offset by an angle of 45°+/−5° to the wafer plane. Second nozzle 42 is also offset by ˜15° from a plane perpendicular to the wafer plane that runs through the center of the isolator 24 and center of the wafer 28.

First nozzle 40 is connected to a first channel 48 disposed in the upper section 34. First channel 48 leads to a gas line 41. Second nozzle 42 is connected to a second channel 50 disposed in the upper section 34. Second channel 50 leads to the gas line 41. First nozzle 40 and second nozzle 42 are connected via the gas line 41 to a reactive gas species source 52.

First nozzle 40 is positioned for bevel and crown processing at a distance of 0.1 to 0.5 mm from the edge of the wafer 28 and 1.3 to 1.8 mm distance from the top surface 30 of the wafer 28. Second nozzle 42 is positioned 0.5 to 3.0 mm in from the edge of the wafer 28 and 0.6 to 1.1 mm distance from the top surface 30 of the wafer 28. Radial position of the nozzles and distance from the wafer surface is dependent upon desired edge exclusion area and is also process and film dependant.

Reactive gas species source 52 either provides a reactive gas species or component reactants for forming the reactive gas species. Reactive gas species can be generated via near atmospheric pressure techniques. This includes near atmospheric capacitively coupled plasma source (i.e., APJET), as described in U.S. Pat. No. 5,961,772, incorporated herein by reference or inductively coupled plasma discharge (i.e., ICP torch), as described in U.S. Pat. No. 6,660,177, incorporated herein by reference or combustion flame. A combustion flame technique (including apparatus and method) for producing reactive gas species is described in a pending U.S. Patent Application No.______ , filed on Sep. 19, 2005, titled “Substrate Processing Method and Apparatus Using a Combustion Flame” and is incorporated herein by reference.

Spontaneous etchants, for example F₂, O₃, or HF can also be used. Advantageously, none of these reactive species techniques produce ion bombardment characteristic of an ionic plasma thus minimizing surface and device damage potential. Further, none of these techniques requires a vacuum chamber together with associated equipment.

An upper purge plenum 54 disposed in the upper section 34 extends at or near the edge of the top surface of the wafer 28, above and across an area of the wafer to be processed to at or near another edge of the top surface 30 of the wafer 28. The upper purge plenum 54 is ˜3.0 mm wide and extends for a total path length of ˜37.5 mm. The upper purge plenum 54 is part of a tuned flow system which prevents reactive gas migration out of the processing area 37.

The upper purge plenum 54 is connected to a first purge channel 56 that is connected to a purge gas source 58 via a purge gas line 57. The purge gas source 58 supplies an inert gas, for example, argon that is fed via the first purge channel 56 into the upper purge plenum 54. Although one purge channel is seen disposed in the upper section 34 of the isolator 24, more than one channel may be present for directing a flow of purge gas into the upper purge plenum 54. Purge channels have an inside diameter of 2.00 mm. The flow of purge gas into the upper purge plenum 54 creates a pressure differential in the area of the top surface 30 surrounded by the upper purge plenum 54 resulting in a barrier between the top surface 30 and the edge area 33 of the wafer 28 being processed.

The upper purge plenum 54 is separated from the top surface 30 of the wafer 28 by an inside baffle 60. Inside baffle 60 follows along the inside perimeter of the upper purge plenum 54 and is separated from the wafer 28 by a gap of 0.30 to 0.80 mm. An outside baffle 62 follows along the outside perimeter of the upper purge plenum 54 and is separated from the wafer 28 by a gap of 0.50 to 1.10 mm. As seen, outside baffle 62 is wider and closer to the top surface 30 of the wafer 28 than the inside baffle 60. This facilitates forming a pressure induced barrier around the in-process portion of the wafer 28 by creating a pressure differential biasing a flow of a purge gas in a direction across inside baffle 60 into the processing area 37 of the isolator 24.

A second purge channel 64 is disposed in the lower section 36 of the isolator 24. This is connected by the purge gas line 57 to the purge gas source 58. Second purge channel 64 is for feeding purge gas to a lower purge plenum 66. Similarly to the upper purge plenum 54, the lower purge plenum 66 extends from at or near the edge area 33 of the wafer 28 below and across the bottom surface 32 to at or near another location of the edge of the wafer 28. Similarly to the upper purge plenum 54, the lower purge plenum 66 is disposed between a lower inside baffle 65 and a lower outside baffle 67. The lower purge plenum 66 together with the lower inside baffle 65 and lower outside baffle 67 bias a flow of purge gas in a direction across the lower inside baffle 65 and across the bottom surface 32.

Wafer chuck 26 is movable in r-θ-z directions for positioning the wafer 28 and rotating it within a slot of the isolator 24 between the upper section 34 and lower section 36. Alternatively, the isolator 24 structure can also be moved in r with the chuck moving in θ and z. Once in position the distance between each side of the wafer 28 and the upper section 34 or lower section 36 is 0.30 to 0.80 mm. The slot open area without a wafer 28 is 124.20 to 216.20 mm². The slot open area with a wafer 28 present is 55.20 to 147.20 mm². The exhaust slot width is 93.0 mm.

A gas diffuser 80 extends into the processing chamber 22 providing a flow of inert gas to the processing chamber 22. The gas diffuser 80 is typically of the shower head type design and is connected via a diffuser gas line 82 to the purge gas source 58.

The exhaust plenum 38 together with the exhaust system 39 are an additional part of the tuned flow system which prevent reactive gas migration out of the processing area 37. Exhaust system 39 creates a negative pressure in the exhaust plenum 38 that draws active species gases together with the inert gas, processed byproducts, and condensation away from the processing area 37 and prevents migration of these gases into the device area of the wafer 28.

A heater element 68 is connected by a heater line 70 to a heater power supply 72. The heater element 68 heats the isolator 24 and to a lesser extent, the wafer 28. Heating the isolator 24 is desirable to prevent condensation of gases that can be corrosive to the isolator 24 and potentially introduce contamination into the processing area 37.

The nozzles of the edge area processing system 20, including the first nozzle 40 and second nozzle 42 are made of sapphire. Sapphire is advantageously non-reactive to the chemistries used in substrate processing. This is important since the processing of semiconductor substrates requires trace material contamination analysis at the parts per million level with acceptable addition to the substrate being less than approximately 10¹⁰ atoms/cm². Further, particle additions to the substrate should be zero for sizes greater than approximately 0.1 micron.

It is also, in many situations, desirable to achieve a laminar gas flow from the nozzles. This requires setting the aspect ratio of the nozzle at around 10× length to diameter. Nozzle inside diameters are around 0.254 to 0.279 mm which requires a uniform smooth nozzle bore length of approximately 2.50 mm.

The isolator 24 nozzles including the first nozzle 40 and second nozzle 42 while described as angled relative to the wafer plane at ˜80 degrees and ˜45 degrees respectively can advantageously be angled in a different direction relative to the wafer plane in order to facilitate processing including etching or deposition of a thin film.

A preferred embodiment of the System 20 employs a combustion flame formed of an ignited combustion (igniter not shown) of gaseous reactants in an inert ambient environment. In a preferred embodiment, gaseous reactants include hydrogen (H₂) and nitrogen trifluoride (NF₃) although other combustion constituents may be used. Argon provides the inert environment although other inert gases may be used.

In operation, a wafer 28 is centered on the wafer chuck 26 and then the wafer chuck 26 positions the wafer 28 in the slot of the isolator 24 between the upper section 34 and the lower section 36 for processing. The wafer chuck 26 is commanded to rotate the wafer 28.

Inert gas 76 is allowed to flow into the upper purge plenum 54 and lower purge plenum 66 from the purge gas source 58. Inert gas 76 flows into the upper purge plenum 54 and lower purge plenum 66 at a rate of 100 sccm to 8,000 sccm. Inert gas 76 is also allowed to flow into the processing chamber 22 through the gas diffuser 80. Inert gas 76 flows into the processing chamber 22 at a rate of 500 sccm to 10,000 sccm.

Next, the exhaust system 39 is activated to draw gases and process byproducts including condensation through the exhaust plenum 38. The heater power supply 72 energizes the heater element 68 to heat the isolator 24. Next, reactive species 74 emit from first nozzle 40 and second nozzle 42. Reactive species (or gases in the case of a combustion flame) flow through the nozzles at a rate of 375 sccm to 475 sccm. The reactive species 74 impinge upon the edge area 33 of the wafer 28 as the wafer 28 rotates. The reactive species 74 react with a thin film or contaminant in the edge area 33 of the wafer 28 resulting in a reactant byproduct 78.

The position of the first processing nozzle 40 and second processing nozzle 42 provides for reactive species 74 to “wrap around” the top bevel, crown, bottom bevel of the wafer 28.

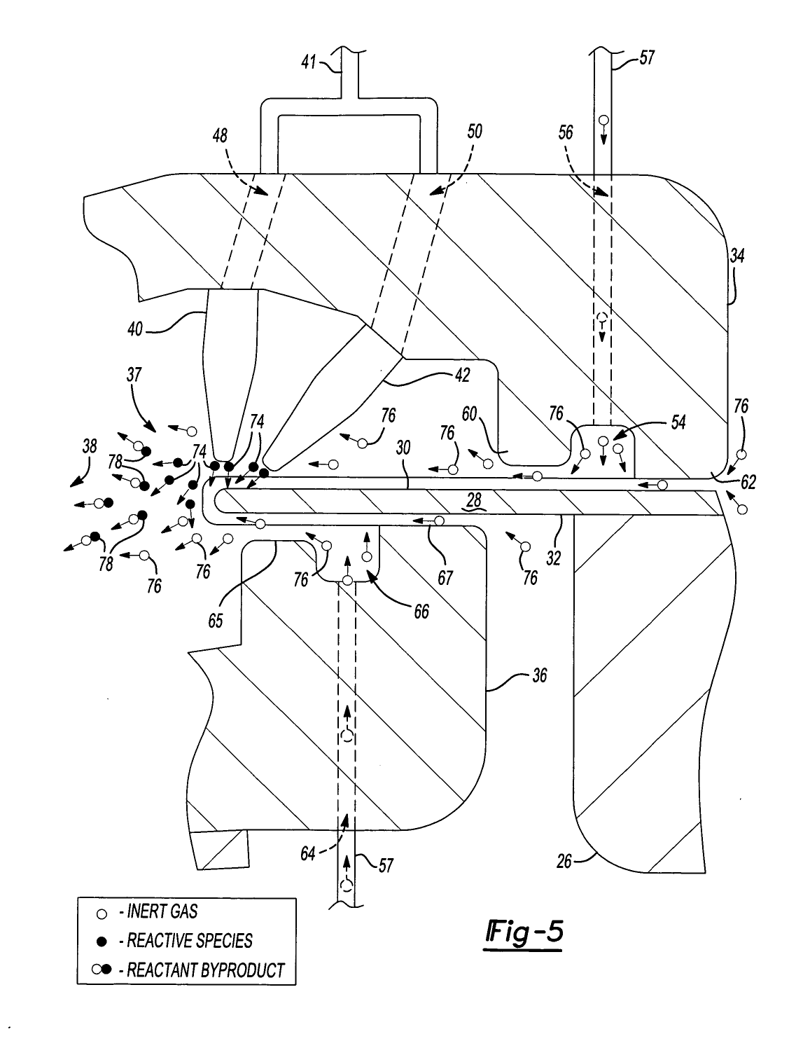

As shown with directional vectors (FIG. 5) the reactive species 74 are prevented from passing out of the isolator 24 by the flow of inert gas 76 working in concert with a pressure differential drawing gases into the exhaust plenum 38 and into the exhaust system 39. This inert gas 76 forms a pressurized barrier in the upper purge plenum 54 and lower purge plenum 66 surrounding the in-process edge area of the wafer. The inside baffle member 60 in cooperation with the outside baffle member 62 biases the flow of insert gas 76 towards the in-process area of the wafer 28. Reactant byproducts 78 formed as a result of the reactive species 74 reacting with a thin film on the wafer 28 surface are drawn away from the in-process area of the wafer 28 into the exhaust plenum 38. Thus, advantageously, reactive species 74 and reactive byproducts 78 are confined to the edge area of the wafer 28 and prevented from migration into other areas of the wafer 28 that may damage wafer component devices. In addition, the pressure differential induced by the exhaust plenum 38 further biases gas flow away from the central portion of the wafer 28.

After processing of the edge area 33 of the wafer 28 is completed the flow of reactive species is stopped. Processing of the edge area 33 of the entire wafer may be accomplished with a single rotation of the wafer 28. Alternatively, more than one rotation may occur and more than one process may be performed including deposition and etching. After the flow of reactive species is stopped a flow of the inert gas 76 continues until the processing chamber 22 is sufficiently evacuated of other gases and condensations. Then the heater element 68 is turned off and the flow of inert gas 76 from the purge gas source 58 is stopped and the wafer 28 is removed and replaced with another wafer for processing.

The described System 20 and associated method for using the system is suitable for etching of target thin films. This includes but is not necessarily limited to tantalum and tantalum nitride; inter-layer dielectrics; backside polymers; and photoresist edge bead.

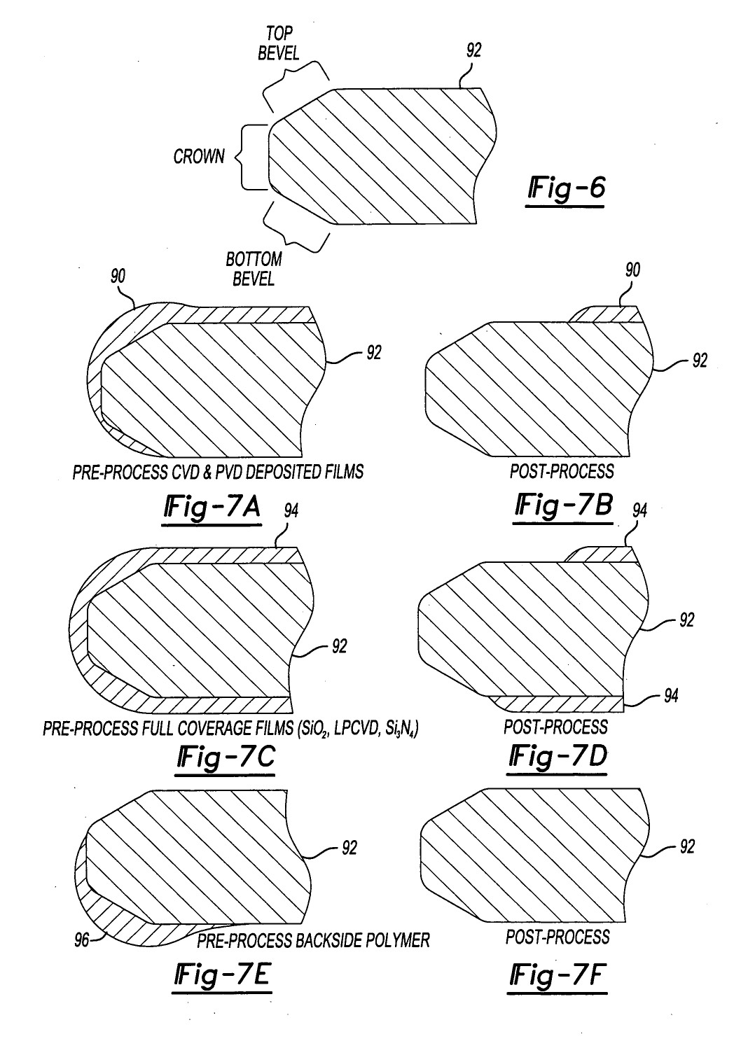

Referring to FIGS. 6 and 7A a film such as deposited through chemical vapor deposition (CVD) or physical vapor deposition (PVD) extends as a thin film 90 over a substrate 92 such as a wafer. The thin film 90 extends from the top surface of the substrate 92 across a top bevel, crown and bottom bevel of the substrate 92. The above-described System 20 can be advantageously used to process the thin film 90 on the substrate 92 resulting in a substrate 92 profile as shown in FIG. 7B.

Referring to FIGS. 6 and 7C a full coverage thin film 94 extends from the top surface across the top bevel, crown and bottom bevel and onto the bottom surface of the substrate 92. Thin films having this profile can include for example thermal SiO₂, and Si₃N₄. Embodiments of the above-described System 20 can be used to process the full coverage thin film 94 on the substrate 92 resulting in a substrate 92 profile as shown in FIG. 7D.

Referring to FIGS. 6 and 7E, a backside polymer thin film 96 extends from at or near the top bevel to across at least a portion of the crown to the bottom bevel and onto the bottom surface of the substrate 92. Embodiments of the above-described System 20 can be used to process the backside polymer thin film 96 on the substrate 92 resulting in a substrate 92 profile as shown in FIG. 7F.

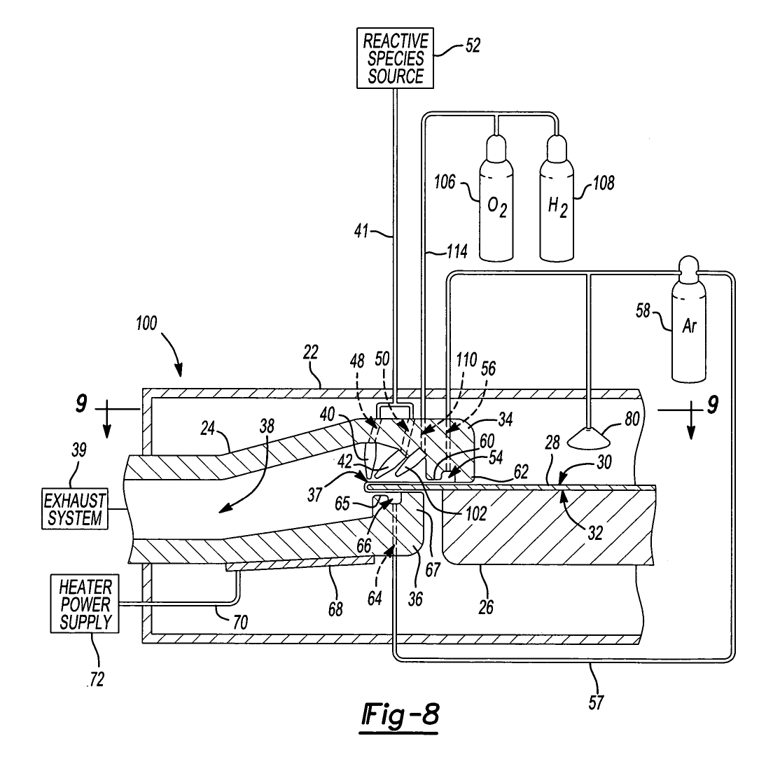

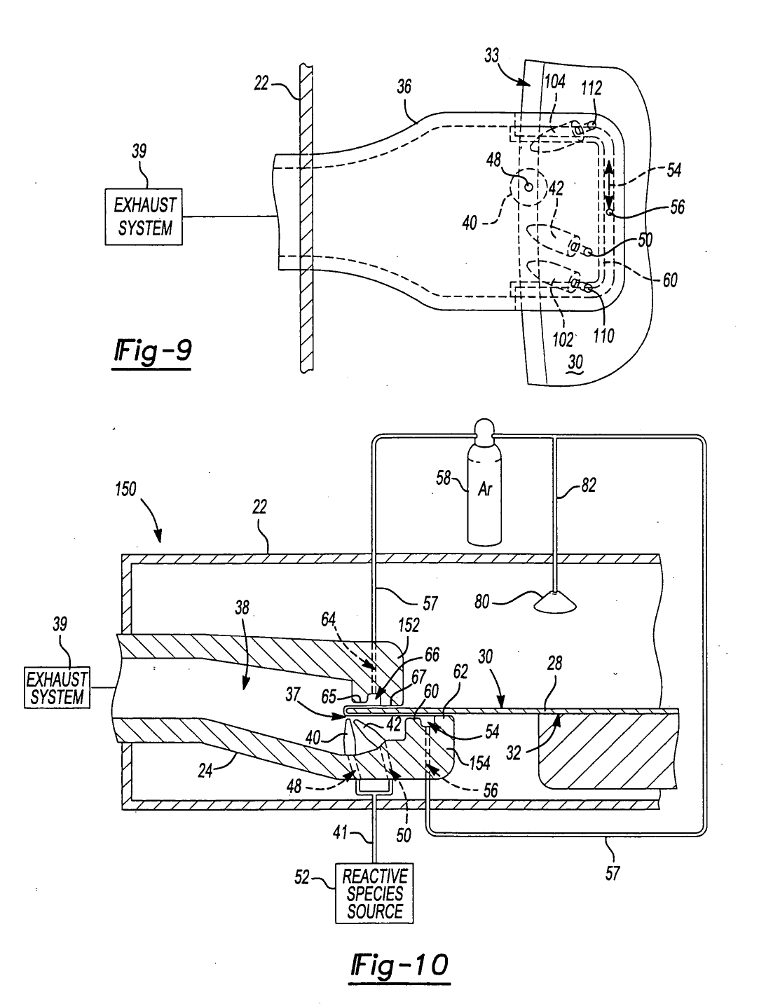

Now referring to FIGS. 8 and 9 an alternative embodiment edge area processing system 100 (the “First Alternative System”) employs a pre-process nozzle 102 and a post-process nozzle 104. Pre-process nozzle 102 and post-process nozzle 104 are connected to a pre-processing gas source of oxygen (O₂)106 and hydrogen (H₂)108 via a first pre-process channel 110 and a second pre-process channel 112 leading to a gas line 114.

Although oxygen 106 and hydrogen 108 are shown as both a pre-treatment and post-treatment gases, other gases may be used. Further, pre-process nozzle 102 and post-process nozzle 104 are for directing a combustion flame onto the top surface 30 of the wafer 28 in the processing area 37. One purpose for a pre-process is to elevate the temperature in the processing area to increase reaction rates and/or to prevent condensation of gases or reaction by-products. Pre-process nozzle 102 and post-process nozzle 104 can also be used to chemically modify the top surface 30 edge area for example by deposition of SiO₂ to enhance selectivity and then immediately follow with an etching process carried out by first nozzle 40 and second nozzle 42. Alternatively, pre-process nozzle 102 and post-process nozzle 104 can operate independently or in cooperation to achieve other process enhancements.

The First Alternative System operates substantially as described above with the addition of igniting a combustion flame of the H₂ 108 and O₂ 106 that emits from the pre-process nozzle 102 and post-process nozzle 104 thus impinging upon the top surface 30 in the processing area 37 as the wafer 28 rotates. Advantageously, the wafer is heated to prevent condensation formation both pre-process and post-process and add thermal energy to increase reaction rates for the wafer 28 processing.

Referring to FIG. 10, a second alternative embodiment edge area processing system 150 (the “Second Alternative System”) is substantially the same as the above-described wafer edge area processing system 20 with a reversal of upper and lower sections of the isolator 24. In the Second Alternative System 150 an alternative upper section 152 extends over the top surface 30 and an alternative lower section 154 extends over the bottom surface 32 with the first nozzle 40 and second nozzle 42 disposed therein. The Second Alternative System performs near edge bottom surface 32 and edge area processing. First nozzle 40 and second nozzle 42 can be positioned such that reactive species “wraps around” the crown to the top bevel region, or aligned such that only the near-edge bottom surface and/or bottom bevel is processed. Operation of the Second Alternative System 150 is substantially as described above.

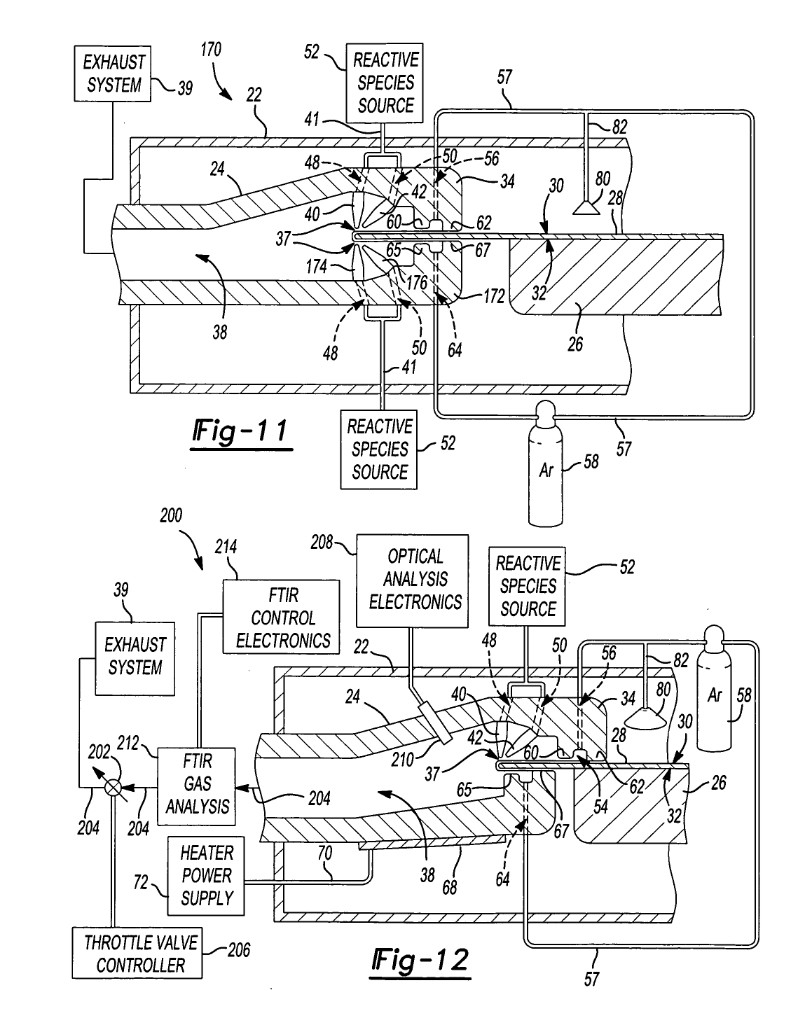

Referring to FIG. 11, a third alternative embodiment edge area processing system 170 (the “Third Alternative System) has a second alternative lower section 172 with a first lower nozzle 174 and second lower nozzle 176 disposed therein. The Third Alternative System 170 configuration allows for simultaneous near edge top surface 30 and near edge bottom surface 32 processing of the wafer 28. Processing by the upper section 34 and second alternative lower section 172 may be conducted independently so that the near edge top surface 30 is processed independent of the near edge bottom surface 32.

Referring to FIG. 12 a fourth alternative embodiment edge area processing system 200 (the “Fourth Alternative System”) includes advanced processed control (“APC”) subsystems added to the above described System 20. APC subsystems include a throttle valve 202 in line with an exhaust stream 204 to monitor and control a pressure differential in the processing area 37 of the isolator 24 to prevent migration of gases including reactive species and reactant byproducts from migrating out of the processing area 37 into other areas of the wafer 28. The throttle valve 202 is connected to a throttle valve controller 206 for adjusting in real-time a preset pressure differential. In this way, a constant pressure differential is maintained even with changing gas loads on the system. Alternatively, a manual throttle valve can be used although pressure differential is then gas load dependent.

Optical analysis electronics 208 are connected to a fiber optic coupler 210 disposed in the upper section 34 of the isolator 24 in position to receive photon emission from reactive processes. The optical analysis electronics 208 is used to observe and analyze reactive processes to determine presence of reactive species and/or relative concentration of reactive species. In another alternative mode of this feature, optical emission spectroscopy can be used to infer etch end points based on reactive species and/or etched products observed to be present in the region where the chemical reaction in taking place. An FTIR gas analysis system 212 connected to FTIR control electronics 214 is in line with the exhaust stream 204 for analysis of the gas effluents exhausted from the isolator 24 using an FTIR technique. Information from the FTIR gas analysis system 212 and FTIR control electronic 214 is used to determine the “health” and condition of the reactive gas delivery system and also for end point detection. For the FTIR technique, the exhaust stream 204 is routed through an optical cell containing an infrared (IR) source and a detector. A dedicated controller and host computer (not shown) operates the gas cell. Commercial FTIR systems are available.

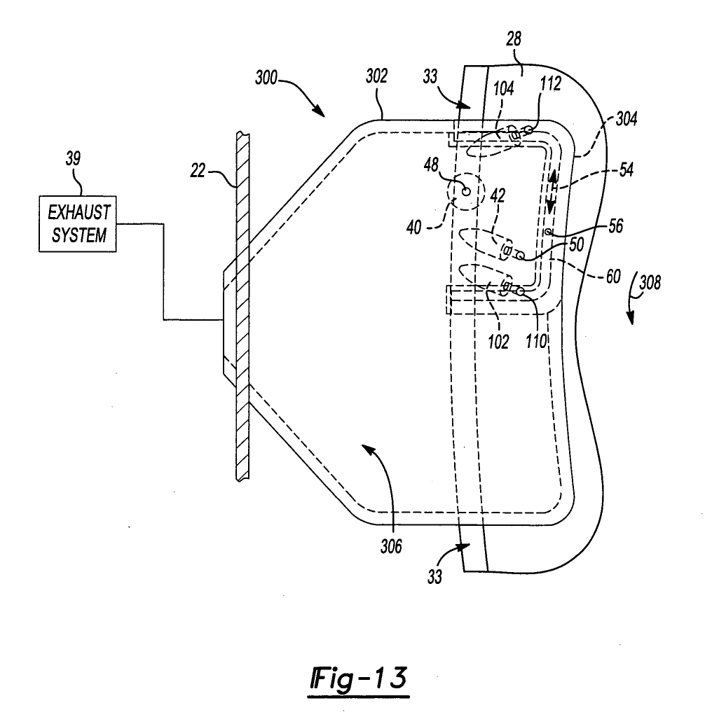

Referring to FIG. 13, a fifth alternative embodiment edge area processing system 300 (the “Fifth Alternative System”) has an extended isolator housing 302 with a nozzle assembly 304 disposed to one side of an expanded exhaust plenum 306. The nozzle assembly 304 is essentially the upper section 34 as shown in FIG. 9 of the First Alternative System with a corresponding unseen lower section 36 as shown in FIG. 8. In this embodiment the wafer 28 rotates in a treatment direction 308 so that it passes through the nozzle assembly 304 before continuing rotation though the remainder of the extended isolator housing 302. In the Fifth Alternative System the nozzle assembly 304 is displaced to one side of the extended isolator housing 302 to allow for additional collection of reactive species, and reaction byproducts by the expanded exhaust plenum 206. Advantageously, this further prevents the possibility of migration of the reactive species or reaction byproducts into the device area of the wafer 28.

The description of the embodiments is merely exemplary in nature and, thus, variations that do not depart from the gist of the invention are intended to be within the scope of the invention. Such variations are not to be regarded as a departure from the spirit and scope of the invention.

What is claimed is:

1. A substrate edge processing apparatus, comprising:
a chuck for retaining a substrate;
an isolator member comprising a nozzle manifold and an exhaust plenum wherein the nozzle manifold covers a portion of an edge of the substrate and the exhaust plenum extends away from the substrate;
one or more groves in the nozzle manifold extending from at or near an edge of the substrate then above and across a near edge surface of the substrate to at or near the edge of the substrate for forming a plenum for restricting flow of a reactive species to the near edge of the substrate;
one or more nozzles disposed in the nozzle manifold wherein at least one of the one or more nozzles are disposed in the isolator at a angle between perpendicular and horizontal to the top surface of the chuck.

2. A substrate edge processing apparatus, comprising:
a processing chamber maintaining a substantially atmospheric pressure for containing and processing a substrate;
a chuck within the processing chamber for holding and rotating the substrate;
a housing at least partially within the processing chamber having an exhaust portion and an isolator portion for isolating a portion of a surface of the substrate, wherein the exhaust portion of the housing extends away from the surface of the substrate;
at least one gas plenum disposed in the isolator portion open to and facing the surface of the substrate for preventing reactive species from passing out of the housing;
an inert gas line in communication with the at least one gas plenum for supply an inert gas; and
a plurality of nozzles disposed in the isolator portion between the gas plenum and the exhaust plenum wherein at least one of the nozzles is pointed towards the surface of the substrate at an angle less than perpendicular and greater than parallel to the surface of the substrate.

3. A substrate wafer edge processing method for isolating and processing a treatment portion of a wafer wherein the treatment portion extends from the edge of the wafer across a top surface of the wafer to the edge of the wafer, the method comprising:
forming a positive pressure differential barrier between the treatment portion of the wafer and the remainder of the wafer; and
directing a reactive species towards the treatment portion of the wafer at an angle greater than parallel to the top surface of the wafer and less than vertical to the top surface of the wafer.

4. The substrate wafer edge processing method of claim 3 further comprising rotating the wafer on a chuck.

5. The substrate wafer edge processing method of claim 3 further comprising providing one or more plenums at or near the edge of the treatment portion for receiving a flow of a gas and creating a pressure barrier between the treatment portion and the remainder of the wafer.

6. The substrate wafer edge processing method of claim 5 further comprising flowing an inert gas into the one or more plenums.

7. The method of claim 6 wherein the inert gas is argon.

8. The substrate wafer edge processing method of claim 3 wherein the method is performed at a substantially atmospheric pressure.

9. The substrate wafer edge processing method of claim 3 wherein the substrate surface is preheated before directing the combustion flame onto the substrate surface.

10. The substrate wafer edge processing method of claim 3 wherein the substrate surface is preheated proximally to where the combustion flame will be directed.

11. The substrate wafer edge processing method of claim 3 wherein the method is performed in a substantially non-ionized environment.

12. The substrate wafer edge processing method of claim 3 wherein the reactive species are formed of a combustion flame of hydrogen and nitrogen trifluoride.

13. The method of claim 12 wherein the molar ratio of said hydrogen to said nitrogen trifluoride is 3:2.

14. The substrate wafer edge processing method of claim 3 wherein the reactive species are formed of a combustion flame wherein the combustion flame is directed towards an edge area of the wafer.

15. The method of claim 14 wherein the wafer is rotated wherein the edge portion of the wafer surface is etched.

16. The substrate wafer edge processing method of claim 3 wherein a material processed is SiO₂.

17. The substrate wafer edge processing method of claim 3 wherein a material etched is Si.

18. The substrate wafer edge processing method of claim 3 wherein a material etched is Ta.

19. A substrate wafer processed according to the method of claim 3.

20. The substrate wafer edge processing method of claim 3 further comprising:
exhausting gases from the treatment portion of the wafer.

21. A wafer edge processing method comprising:
isolating an area of the wafer to be processed with a pressurized barrier of a gas in one or more plenums;
extending the one or more plenums from at or near a first location on the edge of the wafer to at or near a second location on the edge of the wafer;
directing a flow of a reactive species to a surface of the wafer interior to the pressurized barrier; and
flowing an inert gas exterior of the pressurized barrier for biasing a flow of all gases to within the area of the wafer to be processed.
